(19) United States
(12) Patent Application Publication
(10) Pub. No.: US 2022/0308763 A1
(43) Pub. Date: Sep. 29, 2022

(54) METHOD AND APPARATUS FOR A DICTIONARY COMPRESSION ACCELERATOR

(71) Applicants: James GUILFORD, Northborough, MA (US); Vinodh GOPAL, Westborough, MA (US); Daniel CUTTER, Maynard, MA (US)

(72) Inventors: James GUILFORD, Northborough, MA (US); Vinodh GOPAL, Westborough, MA (US); Daniel CUTTER, Maynard, MA (US)

(21) Appl. No.: 17/214,470

(22) Filed: Mar. 26, 2021

(51) Int. Cl. G06F 3/06; H03M 7/30; H03M 7/40

(52) U.S. Cl. CPC G06F 3/0613; G06F 3/0661; G06F 3/0659; G06F 3/0673; G06F 3/0644; H03M 7/3088; H03M 7/40

(57) ABSTRACT

Apparatus and method for dictionary accelerator compression. For example, one embodiment of an apparatus comprises: a plurality of cores; a compression/decompression accelerator coupled to or integral to one or more of the plurality of cores, the compression/decompression accelerator to perform decompression and compression operations in response to read and write operations, respectively, wherein responsive to notification of a compression job to compress a memory page or a portion thereof, a history buffer associated with the compression/decompression accelerator to is to be initialized with pre-configured dictionary data, the compression/decompression accelerator to match portions of the pre-configured dictionary data with portions of the memory page to generate compressed output data.

### BACKGROUND

### Field of the Invention

This invention relates generally to the field of computer processors. More particularly, the invention relates to a method and apparatus for a dictionary compression accelerator.

### Description of the Related Art

An instruction set, or instruction set architecture (ISA), is the part of the computer architecture related to programming, including the native data types, instructions, register architecture, addressing modes, memory architecture, interrupt and exception handling, and external input and output (I/O). It should be noted that the term “instruction” generally refers herein to macro-instructions—that is instructions that are provided to the processor for execution—as opposed to micro-instructions or micro-ops—that is the result of a processor's decoder decoding macro-instructions. The micro-instructions or micro-ops can be configured to instruct an execution unit on the processor to perform operations to implement the logic associated with the macro-instruction.

The ISA is distinguished from the microarchitecture, which is the set of processor design techniques used to implement the instruction set. Processors with different microarchitectures can share a common instruction set. For example, Intel® Pentium 4 processors, Intel® Core™ processors, and processors from Advanced Micro Devices, Inc. of Sunnyvale Calif. implement nearly identical versions of the x86 instruction set (with some extensions that have been added with newer versions), but have different internal designs. For example, the same register architecture of the ISA may be implemented in different ways in different microarchitectures using well-known techniques, including dedicated physical registers, one or more dynamically allocated physical registers using a register renaming mechanism (e.g., the use of a Register Alias Table (RAT), a Reorder Buffer (ROB) and a retirement register file). Unless otherwise specified, the phrases register architecture, register file, and register are used herein to refer to that which is visible to the software/programmer and the manner in which instructions specify registers. Where a distinction is required, the adjective “logical,” “architectural,” or “software visible” will be used to indicate registers/files in the register architecture, while different adjectives will be used to designate registers in a given microarchitecture (e.g., physical register, reorder buffer, retirement register, register pool).

### BRIEF DESCRIPTION OF THE DRAWINGS

A better understanding of the present invention can be obtained from the following detailed description in conjunction with the following drawings, in which:

A better understanding of the present invention can be obtained from the following detailed description in conjunction with the following drawings, in which:

FIG. 1 illustrates an example computer system architecture;

FIG. 2 illustrates a processor comprising a plurality of cores;

FIG. 3A illustrates a plurality of stages of a processing pipeline;

FIG. 3B illustrates details of one embodiment of a core;

FIG. 4 illustrates execution circuitry in accordance with one embodiment;

FIG. 5 illustrates one embodiment of a register architecture;

FIG. 6 illustrates one example of an instruction format;

FIG. 7 illustrates addressing techniques in accordance with one embodiment;

FIG. 8 illustrates one embodiment of an instruction prefix;

FIGS. 9A-D illustrate embodiments of how the R, X, and B fields of the prefix are used;

FIGS. 10A-B illustrate examples of a second instruction prefix;

FIG. 11 illustrates payload bytes of one embodiment of an instruction prefix;

FIG. 12 illustrates instruction conversion and binary translation implementations;

FIG. 13 illustrates a hardware processor with a compression/decompression accelerator according to embodiments of the disclosure;

FIG. 14 illustrates a compression engine in accordance with one embodiment of the invention;

FIG. 15 illustrates a flow diagram according to embodiments of the disclosure;

FIG. 16 illustrates one embodiment of a compression control/state data structure; and

FIG. 17 illustrates internal state included in one embodiment of the control/state data structure.

### DETAILED DESCRIPTION

In the following description, for the purposes of explanation, numerous specific details are set forth in order to provide a thorough understanding of the embodiments of the invention described below. It will be apparent, however, to one skilled in the art that the embodiments of the invention may be practiced without some of these specific details. In other instances, well-known structures and devices are shown in block diagram form to avoid obscuring the underlying principles of the embodiments of the invention.

### Exemplary Computer Architectures

Detailed below are describes of exemplary computer architectures. Other system designs and configurations known in the arts for laptops, desktops, handheld PCs, personal digital assistants, engineering workstations, servers, network devices, network hubs, switches, embedded processors, digital signal processors (DSPs), graphics devices, video game devices, set-top boxes, micro controllers, cell phones, portable media players, hand held devices, and various other electronic devices, are also suitable. In general, a huge variety of systems or electronic devices capable of incorporating a processor and/or other execution logic as disclosed herein are generally suitable.

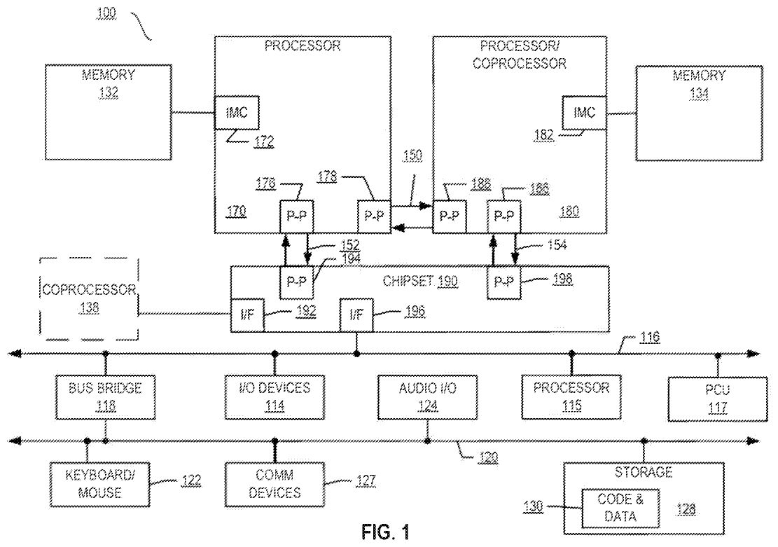

FIG. 1 illustrates embodiments of an exemplary system. Multiprocessor system 100 is a point-to-point interconnect system and includes a plurality of processors including a first processor 170 and a second processor 180 coupled via a point-to-point interconnect 150. In some embodiments, the first processor 170 and the second processor 180 are homogeneous. In some embodiments, first processor 170 and the second processor 180 are heterogenous.

Processors 170 and 180 are shown including integrated memory controller (IMC) units circuitry 172 and 182, respectively. Processor 170 also includes as part of its interconnect controller units point-to-point (P-P) interfaces 176 and 178; similarly, second processor 180 includes P-P interfaces 186 and 188. Processors 170, 180 may exchange information via the point-to-point (P-P) interconnect 150 using P-P interface circuits 178, 188. IMCs 172 and 182 couple the processors 170, 180 to respective memories, namely a memory 132 and a memory 134, which may be portions of main memory locally attached to the respective processors.

Processors 170, 180 may each exchange information with a chipset 190 via individual P-P interconnects 152, 154 using point to point interface circuits 176, 194, 186, 198. Chipset 190 may optionally exchange information with a coprocessor 138 via a high-performance interface 192. In some embodiments, the coprocessor 138 is a special-purpose processor, such as, for example, a high-throughput MIC processor, a network or communication processor, compression engine, graphics processor, GPGPU, embedded processor, or the like.

A shared cache (not shown) may be included in either processor 170, 180 or outside of both processors, yet connected with the processors via P-P interconnect, such that either or both processors' local cache information may be stored in the shared cache if a processor is placed into a low power mode.

Chipset 190 may be coupled to a first interconnect 116 via an interface 196. In some embodiments, first interconnect 116 may be a Peripheral Component Interconnect (PCI) interconnect, or an interconnect such as a PCI Express interconnect or another I/O interconnect. In some embodiments, one of the interconnects couples to a power control unit (PCU) 117, which may include circuitry, software, and/or firmware to perform power management operations with regard to the processors 170, 180 and/or co-processor 138. PCU 117 provides control information to a voltage regulator to cause the voltage regulator to generate the appropriate regulated voltage. PCU 117 also provides control information to control the operating voltage generated. In various embodiments, PCU 117 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 117 is illustrated as being present as logic separate from the processor 170 and/or processor 180. In other cases, PCU 117 may execute on a given one or more of cores (not shown) of processor 170 or 180. In some cases, PCU 117 may be implemented as a microcontroller (dedicated or general-purpose) or other control logic configured to execute its own dedicated power management code, sometimes referred to as P-code. In yet other embodiments, power management operations to be performed by PCU 117 may be implemented externally to a processor, such as by way of a separate power management integrated circuit (PMIC) or another component external to the processor. In yet other embodiments, power management operations to be performed by PCU 117 may be implemented within BIOS or other system software.

Various I/O devices 114 may be coupled to first interconnect 116, along with an interconnect (bus) bridge 118 which couples first interconnect 116 to a second interconnect 120. In some embodiments, one or more additional processor(s) 115, such as coprocessors, high-throughput MIC processors, GPGPU's, accelerators (such as, e.g., graphics accelerators or digital signal processing (DSP) units), field programmable gate arrays (FPGAs), or any other processor, are coupled to first interconnect 116. In some embodiments, second interconnect 120 may be a low pin count (LPC) interconnect. Various devices may be coupled to second interconnect 120 including, for example, a keyboard and/or mouse 122, communication devices 127 and a storage unit circuitry 128. Storage unit circuitry 128 may be a disk drive or other mass storage device which may include instructions/code and data 130, in some embodiments. Further, an audio I/O 124 may be coupled to second interconnect 120. Note that other architectures than the point-to-point architecture described above are possible. For example, instead of the point-to-point architecture, a system such as multiprocessor system 100 may implement a multi-drop interconnect or other such architecture.

### Exemplary Core Architectures, Processors, and Computer Architectures

Processor cores may be implemented in different ways, for different purposes, and in different processors. For instance, implementations of such cores may include: 1) a general purpose in-order core intended for general-purpose computing; 2) a high performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput). Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip that may include on the same die as the described CPU (sometimes referred to as the application core(s) or application processor(s)), the above described coprocessor, and additional functionality. Exemplary core architectures are described next, followed by descriptions of exemplary processors and computer architectures.

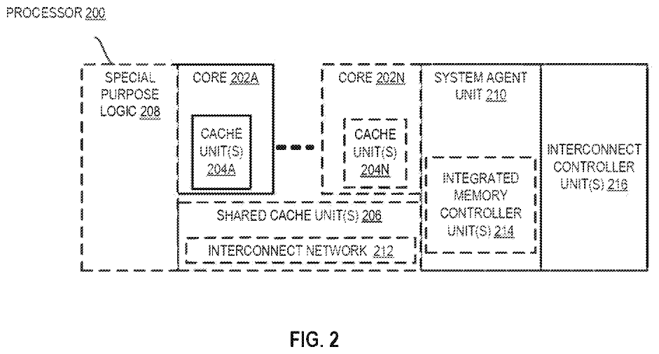

FIG. 2 illustrates a block diagram of embodiments of a processor 200 that may have more than one core, may have an integrated memory controller, and may have integrated graphics. The solid lined boxes illustrate a processor 200 with a single core 202A, a system agent 210, a set of one or more interconnect controller units circuitry 216, while the optional addition of the dashed lined boxes illustrates an alternative processor 200 with multiple cores 202(A)-(N), a set of one or more integrated memory controller unit(s) circuitry 214 in the system agent unit circuitry 210, and special purpose logic 208, as well as a set of one or more interconnect controller units circuitry 216. Note that the processor 200 may be one of the processors 170 or 180, or co-processor 138 or 115 of FIG. 1.

Thus, different implementations of the processor 200 may include: 1) a CPU with the special purpose logic 208 being integrated graphics and/or scientific (throughput) logic (which may include one or more cores, not shown), and the cores 202(A)-(N) being one or more general purpose cores (e.g., general purpose in-order cores, general purpose out-of-order cores, or a combination of the two); 2) a coprocessor with the cores 202(A)-(N) being a large number of special purpose cores intended primarily for graphics and/or scientific (throughput); and 3) a coprocessor with the cores 202(A)-(N) being a large number of general purpose in-order cores. Thus, the processor 200 may be a general-purpose processor, coprocessor or special-purpose processor, such as, for example, a network or communication processor, compression engine, graphics processor, GPGPU (general purpose graphics processing unit circuitry), a high-throughput many integrated core (MIC) coprocessor (including 30 or more cores), embedded processor, or the like. The processor may be implemented on one or more chips. The processor 200 may be a part of and/or may be implemented on one or more substrates using any of a number of process technologies, such as, for example, BiCMOS, CMOS, or NMOS.

A memory hierarchy includes one or more levels of cache unit(s) circuitry 204(A)-(N) within the cores 202(A)-(N), a set of one or more shared cache units circuitry 206, and external memory (not shown) coupled to the set of integrated memory controller units circuitry 214. The set of one or more shared cache units circuitry 206 may include one or more mid-level caches, such as level 2 (L2), level 3 (L3), level 4 (L4), or other levels of cache, such as a last level cache (LLC), and/or combinations thereof. While in some embodiments ring-based interconnect network circuitry 212 interconnects the special purpose logic 208 (e.g., integrated graphics logic), the set of shared cache units circuitry 206, and the system agent unit circuitry 210, alternative embodiments use any number of well-known techniques for interconnecting such units. In some embodiments, coherency is maintained between one or more of the shared cache units circuitry 206 and cores 202(A)-(N).

In some embodiments, one or more of the cores 202(A)-(N) are capable of multi-threading. The system agent unit circuitry 210 includes those components coordinating and operating cores 202(A)-(N). The system agent unit circuitry 210 may include, for example, power control unit (PCU) circuitry and/or display unit circuitry (not shown). The PCU may be or may include logic and components needed for regulating the power state of the cores 202(A)-(N) and/or the special purpose logic 208 (e.g., integrated graphics logic). The display unit circuitry is for driving one or more externally connected displays.

The cores 202(A)-(N) may be homogenous or heterogeneous in terms of architecture instruction set; that is, two or more of the cores 202(A)-(N) may be capable of executing the same instruction set, while other cores may be capable of executing only a subset of that instruction set or a different instruction set.

Exemplary Core Architectures

In-Order and Out-of-Order Core Block Diagram

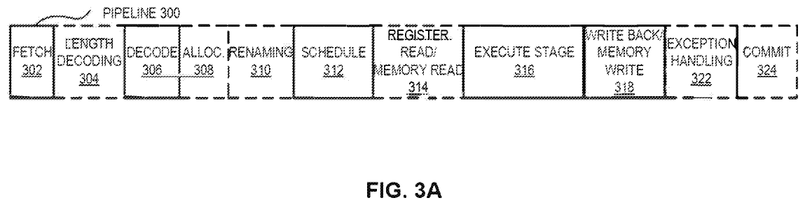

FIG. 3(A) is a block diagram illustrating both an exemplary in-order pipeline and an exemplary register renaming, out-of-order issue/execution pipeline according to embodiments of the invention. FIG. 3(B) is a block diagram illustrating both an exemplary embodiment of an in-order architecture core and an exemplary register renaming, out-of-order issue/execution architecture core to be included in a processor according to embodiments of the invention. The solid lined boxes in FIGS. 3(A)-(B) illustrate the in-order pipeline and in-order core, while the optional addition of the dashed lined boxes illustrates the register renaming, out-of-order issue/execution pipeline and core. Given that the in-order aspect is a subset of the out-of-order aspect, the out-of-order aspect will be described.

In FIG. 3(A), a processor pipeline 300 includes a fetch stage 302, an optional length decode stage 304, a decode stage 306, an optional allocation stage 308, an optional renaming stage 310, a scheduling (also known as a dispatch or issue) stage 312, an optional register read/memory read stage 314, an execute stage 316, a write back/memory write stage 318, an optional exception handling stage 322, and an optional commit stage 324. One or more operations can be performed in each of these processor pipeline stages. For example, during the fetch stage 302, one or more instructions are fetched from instruction memory, during the decode stage 306, the one or more fetched instructions may be decoded, addresses (e.g., load store unit (LSU) addresses) using forwarded register ports may be generated, and branch forwarding (e.g., immediate offset or an link register (LR)) may be performed. In one embodiment, the decode stage 306 and the register read/memory read stage 314 may be combined into one pipeline stage. In one embodiment, during the execute stage 316, the decoded instructions may be executed, LSU address/data pipelining to an Advanced Microcontroller Bus (AHB) interface may be performed, multiply and add operations may be performed, arithmetic operations with branch results may be performed, etc.

By way of example, the exemplary register renaming, out-of-order issue/execution core architecture may implement the pipeline 300 as follows: 1) the instruction fetch 338 performs the fetch and length decoding stages 302 and 304; 2) the decode unit circuitry 340 performs the decode stage 306; 3) the rename/allocator unit circuitry 352 performs the allocation stage 308 and renaming stage 310; 4) the scheduler unit(s) circuitry 356 performs the schedule stage 312; 5) the physical register file(s) unit(s) circuitry 358 and the memory unit circuitry 370 perform the register read/memory read stage 314; the execution cluster 360 perform the execute stage 316; 6) the memory unit circuitry 370 and the physical register file(s) unit(s) circuitry 358 perform the write back/memory write stage 318; 7) various units (unit circuitry) may be involved in the exception handling stage 322; and 8) the retirement unit circuitry 354 and the physical register file(s) unit(s) circuitry 358 perform the commit stage 324.

FIG. 3(B) shows processor core 390 including front-end unit circuitry 330 coupled to an execution engine unit circuitry 350, and both are coupled to a memory unit circuitry 370. The core 390 may be a reduced instruction set computing (RISC) core, a complex instruction set computing (CISC) core, a very long instruction word (VLIW) core, or a hybrid or alternative core type. As yet another option, the core 390 may be a special-purpose core, such as, for example, a network or communication core, compression engine, coprocessor core, general purpose computing graphics processing unit (GPGPU) core, graphics core, or the like.

The front end unit circuitry 330 may include branch prediction unit circuitry 332 coupled to an instruction cache unit circuitry 334, which is coupled to an instruction translation lookaside buffer (TLB) 336, which is coupled to instruction fetch unit circuitry 338, which is coupled to decode unit circuitry 340. In one embodiment, the instruction cache unit circuitry 334 is included in the memory unit circuitry 370 rather than the front-end unit circuitry 330. The decode unit circuitry 340 (or decoder) may decode instructions, and generate as an output one or more micro-operations, micro-code entry points, microinstructions, other instructions, or other control signals, which are decoded from, or which otherwise reflect, or are derived from, the original instructions. The decode unit circuitry 340 may further include an address generation unit circuitry (AGU, not shown). In one embodiment, the AGU generates an LSU address using forwarded register ports, and may further perform branch forwarding (e.g., immediate offset branch forwarding, LR register branch forwarding, etc.). The decode unit circuitry 340 may be implemented using various different mechanisms. Examples of suitable mechanisms include, but are not limited to, look-up tables, hardware implementations, programmable logic arrays (PLAs), microcode read only memories (ROMs), etc. In one embodiment, the core 390 includes a microcode ROM (not shown) or other medium that stores microcode for certain macroinstructions (e.g., in decode unit circuitry 340 or otherwise within the front end unit circuitry 330). In one embodiment, the decode unit circuitry 340 includes a micro-operation (micro-op) or operation cache (not shown) to hold/cache decoded operations, micro-tags, or micro-operations generated during the decode or other stages of the processor pipeline 300. The decode unit circuitry 340 may be coupled to rename/allocator unit circuitry 352 in the execution engine unit circuitry 350.

The execution engine circuitry 350 includes the rename/allocator unit circuitry 352 coupled to a retirement unit circuitry 354 and a set of one or more scheduler(s) circuitry 356. The scheduler(s) circuitry 356 represents any number of different schedulers, including reservations stations, central instruction window, etc. In some embodiments, the scheduler(s) circuitry 356 can include arithmetic logic unit (ALU) scheduler/scheduling circuitry, ALU queues, arithmetic generation unit (AGU) scheduler/scheduling circuitry, AGU queues, etc. The scheduler(s) circuitry 356 is coupled to the physical register file(s) circuitry 358. Each of the physical register file(s) circuitry 358 represents one or more physical register files, different ones of which store one or more different data types, such as scalar integer, scalar floating-point, packed integer, packed floating-point, vector integer, vector floating-point, status (e.g., an instruction pointer that is the address of the next instruction to be executed), etc. In one embodiment, the physical register file(s) unit circuitry 358 includes vector registers unit circuitry, writemask registers unit circuitry, and scalar register unit circuitry. These register units may provide architectural vector registers, vector mask registers, general-purpose registers, etc. The physical register file(s) unit(s) circuitry 358 is overlapped by the retirement unit circuitry 354 (also known as a retire queue or a retirement queue) to illustrate various ways in which register renaming and out-of-order execution may be implemented (e.g., using a reorder buffer(s) (ROB(s)) and a retirement register file(s); using a future file(s), a history buffer(s), and a retirement register file(s); using a register maps and a pool of registers; etc.). The retirement unit circuitry 354 and the physical register file(s) circuitry 358 are coupled to the execution cluster(s) 360. The execution cluster(s) 360 includes a set of one or more execution units circuitry 362 and a set of one or more memory access circuitry 364. The execution units circuitry 362 may perform various arithmetic, logic, floating-point or other types of operations (e.g., shifts, addition, subtraction, multiplication) and on various types of data (e.g., scalar floating-point, packed integer, packed floating-point, vector integer, vector floating-point). While some embodiments may include a number of execution units or execution unit circuitry dedicated to specific functions or sets of functions, other embodiments may include only one execution unit circuitry or multiple execution units/execution unit circuitry that all perform all functions. The scheduler(s) circuitry 356, physical register file(s) unit(s) circuitry 358, and execution cluster(s) 360 are shown as being possibly plural because certain embodiments create separate pipelines for certain types of data/operations (e.g., a scalar integer pipeline, a scalar floating-point/packed integer/packed floating-point/vector integer/vector floating-point pipeline, and/or a memory access pipeline that each have their own scheduler circuitry, physical register file(s) unit circuitry, and/or execution cluster—and in the case of a separate memory access pipeline, certain embodiments are implemented in which only the execution cluster of this pipeline has the memory access unit(s) circuitry 364). It should also be understood that where separate pipelines are used, one or more of these pipelines may be out-of-order issue/execution and the rest in-order.

In some embodiments, the execution engine unit circuitry 350 may perform load store unit (LSU) address/data pipelining to an Advanced Microcontroller Bus (AHB) interface (not shown), and address phase and writeback, data phase load, store, and branches.

The set of memory access circuitry 364 is coupled to the memory unit circuitry 370, which includes data TLB unit circuitry 372 coupled to a data cache circuitry 374 coupled to a level 2 (L2) cache circuitry 376. In one exemplary embodiment, the memory access units circuitry 364 may include a load unit circuitry, a store address unit circuit, and a store data unit circuitry, each of which is coupled to the data TLB circuitry 372 in the memory unit circuitry 370. The instruction cache circuitry 334 is further coupled to a level 2 (L2) cache unit circuitry 376 in the memory unit circuitry 370. In one embodiment, the instruction cache 334 and the data cache 374 are combined into a single instruction and data cache (not shown) in L2 cache unit circuitry 376, a level 3 (L3) cache unit circuitry (not shown), and/or main memory. The L2 cache unit circuitry 376 is coupled to one or more other levels of cache and eventually to a main memory.

The core 390 may support one or more instructions sets (e.g., the x86 instruction set (with some extensions that have been added with newer versions); the MIPS instruction set; the ARM instruction set (with optional additional extensions such as NEON)), including the instruction(s) described herein. In one embodiment, the core 390 includes logic to support a packed data instruction set extension (e.g., AVX1, AVX2), thereby allowing the operations used by many multimedia applications to be performed using packed data.

Exemplary Execution Unit(s) Circuitry

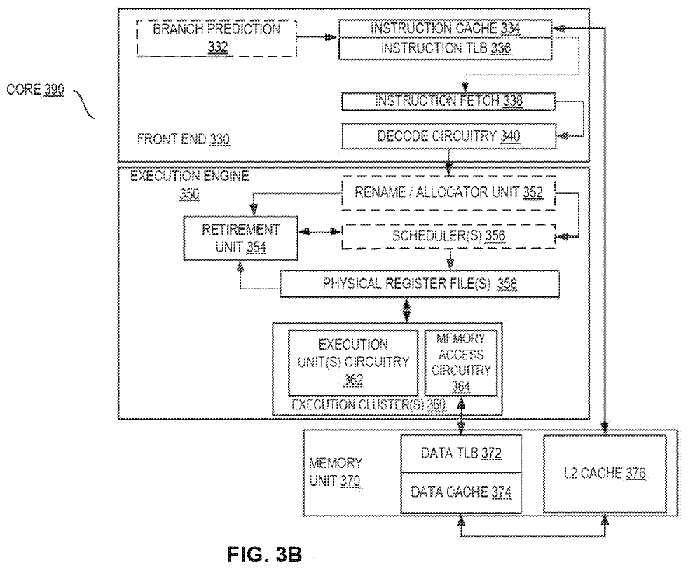

FIG. 4 illustrates embodiments of execution unit(s) circuitry, such as execution unit(s) circuitry 362 of FIG. 3(B). As illustrated, execution unit(s) circuitry 362 may include one or more ALU circuits 401, vector/SIMD unit circuits 403, load/store unit circuits 405, and/or branch/jump unit circuits 407. ALU circuits 401 perform integer arithmetic and/or Boolean operations. Vector/SIMD unit circuits 403 perform vector/SIMD operations on packed data (such as SIMD/vector registers). Load/store unit circuits 405 execute load and store instructions to load data from memory into registers or store from registers to memory. Load/store unit circuits 405 may also generate addresses. Branch/jump unit circuits 407 cause a branch or jump to a memory address depending on the instruction. Floating-point unit (FPU) circuits 409 perform floating-point arithmetic. The width of the execution unit(s) circuitry 362 varies depending upon the embodiment and can range from 16-bit to 1,024-bit. In some embodiments, two or more smaller execution units are logically combined to form a larger execution unit (e.g., two 128-bit execution units are logically combined to form a 256-bit execution unit).

Exemplary Register Architecture

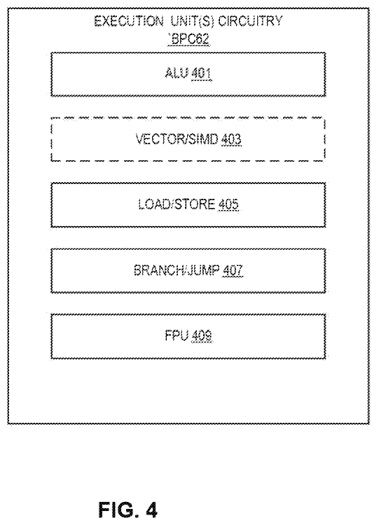

FIG. 5 is a block diagram of a register architecture 500 according to some embodiments. As illustrated, there are vector/SIMD registers 510 that vary from 128-bit to 1,024 bits width. In some embodiments, the vector/SIMD registers 510 are physically 512-bits and, depending upon the mapping, only some of the lower bits are used. For example, in some embodiments, the vector/SIMD registers 510 are ZMM registers which are 512 bits: the lower 256 bits are used for YMM registers and the lower 128 bits are used for XMM registers. As such, there is an overlay of registers. In some embodiments, a vector length field selects between a maximum length and one or more other shorter lengths, where each such shorter length is half the length of the preceding length. Scalar operations are operations performed on the lowest order data element position in a ZMM/YMM/XMM register; the higher order data element positions are either left the same as they were prior to the instruction or zeroed depending on the embodiment.

In some embodiments, the register architecture 500 includes writemask/predicate registers 515. For example, in some embodiments, there are 8 writemask/predicate registers (sometimes called k0 through k7) that are each 16-bit, 32-bit, 64-bit, or 128-bit in size. Writemask/predicate registers 515 may allow for merging (e.g., allowing any set of elements in the destination to be protected from updates during the execution of any operation) and/or zeroing (e.g., zeroing vector masks allow any set of elements in the destination to be zeroed during the execution of any operation). In some embodiments, each data element position in a given writemask/predicate register 515 corresponds to a data element position of the destination. In other embodiments, the writemask/predicate registers 515 are scalable and consists of a set number of enable bits for a given vector element (e.g., 8 enable bits per 64-bit vector element).

The register architecture 500 includes a plurality of general-purpose registers 525. These registers may be 16-bit, 32-bit, 64-bit, etc. and can be used for scalar operations. In some embodiments, these registers are referenced by the names RAX, RBX, RCX, RDX, RBP, RSI, RDI, RSP, and R8 through R15.

In some embodiments, the register architecture 500 includes scalar floating-point register 545 which is used for scalar floating-point operations on 32/64/80-bit floating-point data using the x87 instruction set extension or as MMX registers to perform operations on 64-bit packed integer data, as well as to hold operands for some operations performed between the MMX and XMM registers.

One or more flag registers 540 (e.g., EFLAGS, RFLAGS, etc.) store status and control information for arithmetic, compare, and system operations. For example, the one or more flag registers 540 may store condition code information such as carry, parity, auxiliary carry, zero, sign, and overflow. In some embodiments, the one or more flag registers 540 are called program status and control registers.

Segment registers 520 contain segment points for use in accessing memory. In some embodiments, these registers are referenced by the names CS, DS, SS, ES, FS, and GS.

Machine specific registers (MSRs) 535 control and report on processor performance. Most MSRs 535 handle system-related functions and are not accessible to an application program. Machine check registers 560 consist of control, status, and error reporting MSRs that are used to detect and report on hardware errors.

One or more instruction pointer register(s) 530 store an instruction pointer value. Control register(s) 555 (e.g., CR0-CR4) determine the operating mode of a processor (e.g., processor 170, 180, 138, 115, and/or 200) and the characteristics of a currently executing task. Debug registers 550 control and allow for the monitoring of a processor or core's debugging operations.

Memory management registers 565 specify the locations of data structures used in protected mode memory management. These registers may include a GDTR, IDRT, task register, and a LDTR register.

Alternative embodiments of the invention may use wider or narrower registers. Additionally, alternative embodiments of the invention may use more, less, or different register files and registers.

Instruction Sets

An instruction set architecture (ISA) may include one or more instruction formats. A given instruction format may define various fields (e.g., number of bits, location of bits) to specify, among other things, the operation to be performed (e.g., opcode) and the operand(s) on which that operation is to be performed and/or other data field(s) (e.g., mask). Some instruction formats are further broken down though the definition of instruction templates (or sub-formats). For example, the instruction templates of a given instruction format may be defined to have different subsets of the instruction format's fields (the included fields are typically in the same order, but at least some have different bit positions because there are less fields included) and/or defined to have a given field interpreted differently. Thus, each instruction of an ISA is expressed using a given instruction format (and, if defined, in a given one of the instruction templates of that instruction format) and includes fields for specifying the operation and the operands. For example, an exemplary ADD instruction has a specific opcode and an instruction format that includes an opcode field to specify that opcode and operand fields to select operands (source1/destination and source2); and an occurrence of this ADD instruction in an instruction stream will have specific contents in the operand fields that select specific operands.

Exemplary Instruction Formats

Embodiments of the instruction(s) described herein may be embodied in different formats. Additionally, exemplary systems, architectures, and pipelines are detailed below. Embodiments of the instruction(s) may be executed on such systems, architectures, and pipelines, but are not limited to those detailed.

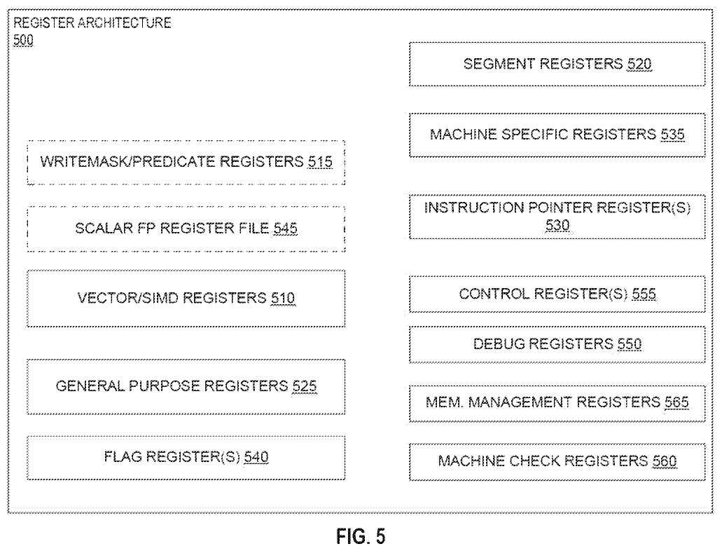

FIG. 6 illustrates embodiments of an instruction format. As illustrated, an instruction may include multiple components including, but not limited to, one or more fields for: one or more prefixes 601, an opcode 603, addressing information 605 (e.g., register identifiers, memory addressing information, etc.), a displacement value 607, and/or an immediate 609. Note that some instructions utilize some or all of the fields of the format whereas others may only use the field for the opcode 603. In some embodiments, the order illustrated is the order in which these fields are to be encoded, however, it should be appreciated that in other embodiments these fields may be encoded in a different order, combined, etc.

The prefix(es) field(s) 601, when used, modifies an instruction. In some embodiments, one or more prefixes are used to repeat string instructions (e.g., 0xF0, 0xF2, 0xF3, etc.), to provide section overrides (e.g., 0x2E, 0x36, 0x3E, 0x26, 0x64, 0x65, 0x2E, 0x3E, etc.), to perform bus lock operations, and/or to change operand (e.g., 0x66) and address sizes (e.g., 0x67). Certain instructions require a mandatory prefix (e.g., 0x66, 0xF2, 0xF3, etc.). Certain of these prefixes may be considered “legacy” prefixes. Other prefixes, one or more examples of which are detailed herein, indicate, and/or provide further capability, such as specifying particular registers, etc. The other prefixes typically follow the “legacy” prefixes.

The opcode field 603 is used to at least partially define the operation to be performed upon a decoding of the instruction. In some embodiments, a primary opcode encoded in the opcode field 603 is 1, 2, or 3 bytes in length. In other embodiments, a primary opcode can be a different length. An additional 3-bit opcode field is sometimes encoded in another field.

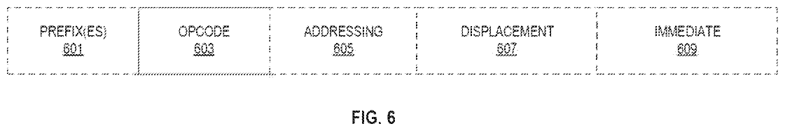

The addressing field 605 is used to address one or more operands of the instruction, such as a location in memory or one or more registers. FIG. 7 illustrates embodiments of the addressing field 605. In this illustration, an optional ModR/M byte 702 and an optional Scale, Index, Base (SIB) byte 704 are shown. The ModR/M byte 702 and the SIB byte 704 are used to encode up to two operands of an instruction, each of which is a direct register or effective memory address. Note that each of these fields are optional in that not all instructions include one or more of these fields. The MOD R/M byte 702 includes a MOD field 742, a register field 744, and R/M field 746.

The content of the MOD field 742 distinguishes between memory access and non-memory access modes. In some embodiments, when the MOD field 742 has a value of b11, a register-direct addressing mode is utilized, and otherwise register-indirect addressing is used.

The register field 744 may encode either the destination register operand or a source register operand, or may encode an opcode extension and not be used to encode any instruction operand. The content of register index field 744, directly or through address generation, specifies the locations of a source or destination operand (either in a register or in memory). In some embodiments, the register field 744 is supplemented with an additional bit from a prefix (e.g., prefix 601) to allow for greater addressing.

The R/M field 746 may be used to encode an instruction operand that references a memory address, or may be used to encode either the destination register operand or a source register operand. Note the R/M field 746 may be combined with the MOD field 742 to dictate an addressing mode in some embodiments.

The SIB byte 704 includes a scale field 752, an index field 754, and a base field 756 to be used in the generation of an address. The scale field 752 indicates scaling factor. The index field 754 specifies an index register to use. In some embodiments, the index field 754 is supplemented with an additional bit from a prefix (e.g., prefix 601) to allow for greater addressing. The base field 756 specifies a base register to use. In some embodiments, the base field 756 is supplemented with an additional bit from a prefix (e.g., prefix 601) to allow for greater addressing. In practice, the content of the scale field 752 allows for the scaling of the content of the index field 754 for memory address generation (e.g., for address generation that uses 2^{scale}*index+base).

Some addressing forms utilize a displacement value to generate a memory address. For example, a memory address may be generated according to 2^{scale}*index+base+displacement, index*scale+displacement, r/m+displacement, instruction pointer (RIP/EIP)+displacement, register+displacement, etc. The displacement may be a 1-byte, 2-byte, 4-byte, etc. value. In some embodiments, a displacement field 607 provides this value. Additionally, in some embodiments, a displacement factor usage is encoded in the MOD field of the addressing field 605 that indicates a compressed displacement scheme for which a displacement value is calculated by multiplying disp8 in conjunction with a scaling factor N that is determined based on the vector length, the value of a b bit, and the input element size of the instruction. The displacement value is stored in the displacement field 607.

In some embodiments, an immediate field 609 specifies an immediate for the instruction. An immediate may be encoded as a 1-byte value, a 2-byte value, a 4-byte value, etc.

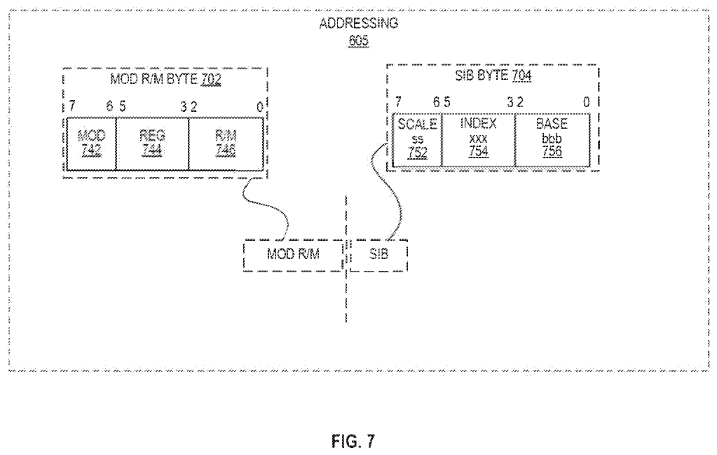

FIG. 8 illustrates embodiments of a first prefix 601(A). In some embodiments, the first prefix 601(A) is an embodiment of a REX prefix. Instructions that use this prefix may specify general purpose registers, 64-bit packed data registers (e.g., single instruction, multiple data (SIMD) registers or vector registers), and/or control registers and debug registers (e.g., CR8-CR15 and DR8-DR15).

Instructions using the first prefix 601(A) may specify up to three registers using 3-bit fields depending on the format: 1) using the reg field 744 and the R/M field 746 of the Mod R/M byte 702; 2) using the Mod R/M byte 702 with the SIB byte 704 including using the reg field 744 and the base field 756 and index field 754; or 3) using the register field of an opcode.

In the first prefix 601(A), bit positions 7:4 are set as 0100. Bit position 3 (W) can be used to determine the operand size, but may not solely determine operand width. As such, when W=0, the operand size is determined by a code segment descriptor (CS.D) and when W=1, the operand size is 64-bit.

Note that the addition of another bit allows for 16 (2⁴) registers to be addressed, whereas the MOD R/M reg field 744 and MOD R/M R/M field 746 alone can each only address 8 registers.

In the first prefix 601(A), bit position 2 (R) may an extension of the MOD R/M reg field 744 and may be used to modify the ModR/M reg field 744 when that field encodes a general purpose register, a 64-bit packed data register (e.g., a SSE register), or a control or debug register. R is ignored when Mod R/M byte 702 specifies other registers or defines an extended opcode.

Bit position 1 (X) X bit may modify the SIB byte index field 754.

Bit position B (B) B may modify the base in the Mod R/M R/M field 746 or the SIB byte base field 756; or it may modify the opcode register field used for accessing general purpose registers (e.g., general purpose registers 525).

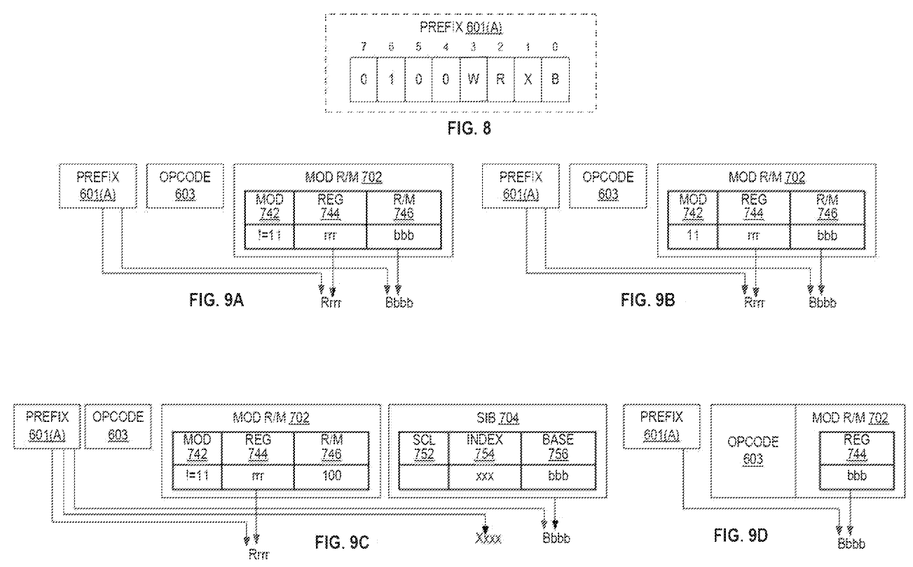

FIGS. 9(A)-(D) illustrate embodiments of how the R, X, and B fields of the first prefix 601(A) are used. FIG. 9(A) illustrates R and B from the first prefix 601(A) being used to extend the reg field 744 and R/M field 746 of the MOD R/M byte 702 when the SIB byte 704 is not used for memory addressing. FIG. 9(B) illustrates R and B from the first prefix 601(A) being used to extend the reg field 744 and R/M field 746 of the MOD R/M byte 702 when the SIB byte 704 is not used (register-register addressing). FIG. 9(C) illustrates R, X, and B from the first prefix 601(A) being used to extend the reg field 744 of the MOD R/M byte 702 and the index field 754 and base field 756 when the SIB byte 704 being used for memory addressing. FIG. 9(D) illustrates B from the first prefix 601(A) being used to extend the reg field 744 of the MOD R/M byte 702 when a register is encoded in the opcode 603.

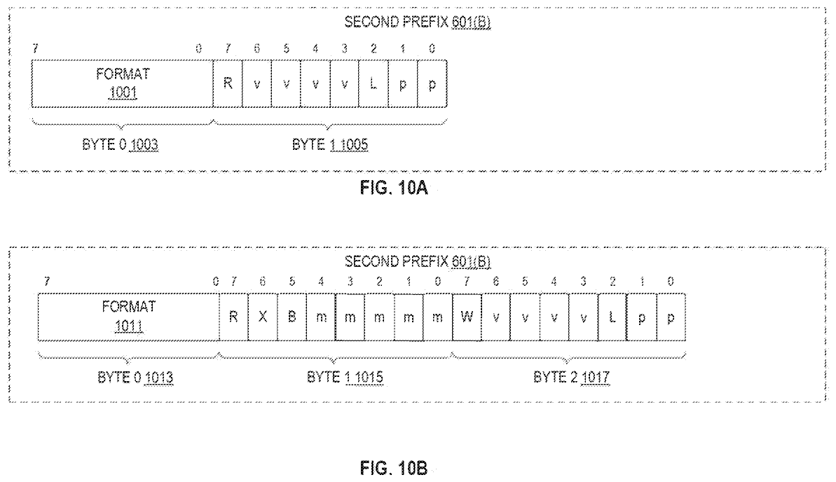

FIGS. 10(A)-(B) illustrate embodiments of a second prefix 601(B). In some embodiments, the second prefix 601(B) is an embodiment of a VEX prefix. The second prefix 601(B) encoding allows instructions to have more than two operands, and allows SIMD vector registers (e.g., vector/SIMD registers 510) to be longer than 64-bits (e.g., 128-bit and 256-bit). The use of the second prefix 601(B) provides for three-operand (or more) syntax. For example, previous two-operand instructions performed operations such as A=A+B, which overwrites a source operand. The use of the second prefix 601(B) enables operands to perform nondestructive operations such as A=B+C.

In some embodiments, the second prefix 601(B) comes in two forms—a two-byte form and a three-byte form. The two-byte second prefix 601(B) is used mainly for 128-bit, scalar, and some 256-bit instructions; while the three-byte second prefix 601(B) provides a compact replacement of the first prefix 601(A) and 3-byte opcode instructions.

FIG. 10(A) illustrates embodiments of a two-byte form of the second prefix 601(B). In one example, a format field 1001 (byte 0 1003) contains the value CSH. In one example, byte 1 1005 includes a “R” value in bit[7]. This value is the complement of the same value of the first prefix 601(A). Bit[2] is used to dictate the length (L) of the vector (where a value of 0 is a scalar or 128-bit vector and a value of 1 is a 256-bit vector). Bits[1:0] provide opcode extensionality equivalent to some legacy prefixes (e.g., 00=no prefix, 01=66H, 10=F3H, and 11=F2H). Bits[6:3] shown as vvvv may be used to: 1) encode the first source register operand, specified in inverted (1s complement) form and valid for instructions with 2 or more source operands; 2) encode the destination register operand, specified in 1s complement form for certain vector shifts; or 3) not encode any operand, the field is reserved and should contain a certain value, such as 1111b.

Instructions that use this prefix may use the Mod R/M R/M field 746 to encode the instruction operand that references a memory address or encode either the destination register operand or a source register operand.

Instructions that use this prefix may use the Mod R/M reg field 744 to encode either the destination register operand or a source register operand, be treated as an opcode extension and not used to encode any instruction operand.

For instruction syntax that support four operands, vvvv, the Mod R/M R/M field 746 and the Mod R/M reg field 744 encode three of the four operands. Bits[7:4] of the immediate 609 are then used to encode the third source register operand.

FIG. 10(B) illustrates embodiments of a three-byte form of the second prefix 601(B). in one example, a format field 1011 (byte 0 1013) contains the value C4H. Byte 1 1015 includes in bits[7:5] “R,” “X,” and “B” which are the complements of the same values of the first prefix 601(A). Bits[4:0] of byte 1 1015 (shown as mmmmm) include content to encode, as need, one or more implied leading opcode bytes. For example, 00001 implies a 0FH leading opcode, 00010 implies a 0F38H leading opcode, 00011 implies a leading 0F3AH opcode, etc.

Bit[7] of byte 2 1017 is used similar to W of the first prefix 601(A) including helping to determine promotable operand sizes. Bit[2] is used to dictate the length (L) of the vector (where a value of 0 is a scalar or 128-bit vector and a value of 1 is a 256-bit vector). Bits[1:0] provide opcode extensionality equivalent to some legacy prefixes (e.g., 00=no prefix, 01=66H, 10=F3H, and 11=F2H). Bits[6:3], shown as vvvv, may be used to: 1) encode the first source register operand, specified in inverted (1s complement) form and valid for instructions with 2 or more source operands; 2) encode the destination register operand, specified in 1s complement form for certain vector shifts; or 3) not encode any operand, the field is reserved and should contain a certain value, such as 1111b.

Instructions that use this prefix may use the Mod R/M R/M field 746 to encode the instruction operand that references a memory address or encode either the destination register operand or a source register operand.

Instructions that use this prefix may use the Mod R/M reg field 744 to encode either the destination register operand or a source register operand, be treated as an opcode extension and not used to encode any instruction operand.

For instruction syntax that support four operands, vvvv, the Mod R/M R/M field 746, and the Mod R/M reg field 744 encode three of the four operands. Bits[7:4] of the immediate 609 are then used to encode the third source register operand.

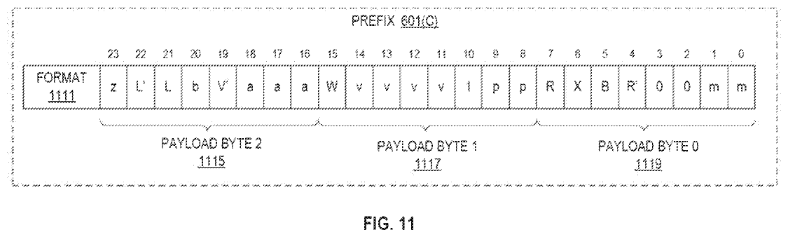

FIG. 11 illustrates embodiments of a third prefix 601(C). In some embodiments, the first prefix 601(A) is an embodiment of an EVEX prefix. The third prefix 601(C) is a four-byte prefix.

The third prefix 601(C) can encode 32 vector registers (e.g., 128-bit, 256-bit, and 512-bit registers) in 64-bit mode. In some embodiments, instructions that utilize a writemask/opmask (see discussion of registers in a previous figure, such as FIG. 5) or predication utilize this prefix. Opmask register allow for conditional processing or selection control. Opmask instructions, whose source/destination operands are opmask registers and treat the content of an opmask register as a single value, are encoded using the second prefix 601(B).

The third prefix 601(C) may encode functionality that is specific to instruction classes (e.g., a packed instruction with “load+op” semantic can support embedded broadcast functionality, a floating-point instruction with rounding semantic can support static rounding functionality, a floating-point instruction with non-rounding arithmetic semantic can support “suppress all exceptions” functionality, etc.).

The first byte of the third prefix 601(C) is a format field 1111 that has a value, in one example, of 62H. Subsequent bytes are referred to as payload bytes 1115-1119 and collectively form a 24-bit value of P[23:0] providing specific capability in the form of one or more fields (detailed herein).

In some embodiments, P[1:0] of payload byte 1119 are identical to the low two mmmmm bits. P[3:2] are reserved in some embodiments. Bit P[4] (R′) allows access to the high 16 vector register set when combined with P[7] and the ModR/M reg field 744. P[6] can also provide access to a high 16 vector register when SIB-type addressing is not needed. P[7:5] consist of an R, X, and B which are operand specifier modifier bits for vector register, general purpose register, memory addressing and allow access to the next set of 8 registers beyond the low 8 registers when combined with the ModR/M register field 744 and ModR/M R/M field 746. P[9:8] provide opcode extensionality equivalent to some legacy prefixes (e.g., 00=no prefix, 01=66H, 10=F3H, and 11=F2H). P[10] in some embodiments is a fixed value of 1. P[14:11], shown as vvvv, may be used to: 1) encode the first source register operand, specified in inverted (1s complement) form and valid for instructions with 2 or more source operands; 2) encode the destination register operand, specified in 1s complement form for certain vector shifts; or 3) not encode any operand, the field is reserved and should contain a certain value, such as 1111b.

P[15] is similar to W of the first prefix 601(A) and second prefix 611(B) and may serve as an opcode extension bit or operand size promotion.

P[18:16] specify the index of a register in the opmask (writemask) registers (e.g., writemask/predicate registers 515). In one embodiment of the invention, the specific value aaa=000 has a special behavior implying no opmask is used for the particular instruction (this may be implemented in a variety of ways including the use of a opmask hardwired to all ones or hardware that bypasses the masking hardware). When merging, vector masks allow any set of elements in the destination to be protected from updates during the execution of any operation (specified by the base operation and the augmentation operation); in other one embodiment, preserving the old value of each element of the destination where the corresponding mask bit has a 0. In contrast, when zeroing vector masks allow any set of elements in the destination to be zeroed during the execution of any operation (specified by the base operation and the augmentation operation); in one embodiment, an element of the destination is set to 0 when the corresponding mask bit has a 0 value. A subset of this functionality is the ability to control the vector length of the operation being performed (that is, the span of elements being modified, from the first to the last one); however, it is not necessary that the elements that are modified be consecutive. Thus, the opmask field allows for partial vector operations, including loads, stores, arithmetic, logical, etc. While embodiments of the invention are described in which the opmask field's content selects one of a number of opmask registers that contains the opmask to be used (and thus the opmask field's content indirectly identifies that masking to be performed), alternative embodiments instead or additional allow the mask write field's content to directly specify the masking to be performed.

P[19] can be combined with P[14:11] to encode a second source vector register in a non-destructive source syntax which can access an upper 16 vector registers using P[19]. P[20] encodes multiple functionalities, which differs across different classes of instructions and can affect the meaning of the vector length/rounding control specifier field (P[22:21]). P[23] indicates support for merging-writemasking (e.g., when set to 0) or support for zeroing and merging-writemasking (e.g., when set to 1).

Exemplary embodiments of encoding of registers in instructions using the third prefix 601(C) are detailed in the following tables.

TABLE 1
32-Register Support in 64-bit Mode

| | 4 | 3 | [2:0] | REG. TYPE | COMMON USAGES |
|---|---|---|---|---|---|
| REG | R′ | R | ModR/M | GPR, | Destination or Source |
| | | | reg | Vector | |
| vvvv | V′ | vvvv | | GPR, | 2nd Source or |
| | | | | Vector | Destination |
| RM | X | B | ModR/M | GPR, | 1st Source or |
| | | | R/M | Vector | Destination |
| BASE | 0 | B | ModR/M | GPR | Memory addressing |
| | | | R/M | | |
| INDEX | 0 | X | SIB.index | GPR | Memory addressing |
| VIDX | V′ | X | SIB.index | Vector | VSIB memory |
| | | | | | addressing |

TABLE 2
Encoding Register Specifiers in 32-bit Mode

| | [2:0] | REG. TYPE | COMMON USAGES |
|---|---|---|---|
| REG | ModR/M reg | GPR, Vector | Destination or Source |
| VVVV | vvvv | GPR, Vector | 2^{nd} Source or Destination |
| RM | ModR/M R/M | GPR, Vector | 1^{st} Source or Destination |
| BASE | ModR/M R/M | GPR | Memory addressing |
| INDEX | SIB.index | GPR | Memory addressing |
| VIDX | SIB.index | Vector | VSIB memory addressing |

TABLE 3
Opmask Register Specifier Encoding

| | [2:0] | REG. TYPE | COMMON USAGES |
|---|---|---|---|
| REG | ModR/M Reg | k0-k7 | Source |
| VVVV | vvvv | k0-k7 | 2^{nd} Source |
| RM | ModR/M R/M | k0-7 | 1^{st} Source |
| {k1] | aaa | k0¹-k7 | Opmask |

Program code may be applied to input instructions to perform the functions described herein and generate output information. The output information may be applied to one or more output devices, in known fashion. For purposes of this application, a processing system includes any system that has a processor, such as, for example, a digital signal processor (DSP), a microcontroller, an application specific integrated circuit (ASIC), or a microprocessor.

The program code may be implemented in a high-level procedural or object-oriented programming language to communicate with a processing system. The program code may also be implemented in assembly or machine language, if desired. In fact, the mechanisms described herein are not limited in scope to any particular programming language. In any case, the language may be a compiled or interpreted language.

Embodiments of the mechanisms disclosed herein may be implemented in hardware, software, firmware, or a combination of such implementation approaches. Embodiments of the invention may be implemented as computer programs or program code executing on programmable systems comprising at least one processor, a storage system (including volatile and non-volatile memory and/or storage elements), at least one input device, and at least one output device.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that actually make the logic or processor.

Such machine-readable storage media may include, without limitation, non-transitory, tangible arrangements of articles manufactured or formed by a machine or device, including storage media such as hard disks, any other type of disk including floppy disks, optical disks, compact disk read-only memories (CD-ROMs), compact disk rewritable's (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), phase change memory (PCM), magnetic or optical cards, or any other type of media suitable for storing electronic instructions.

Accordingly, embodiments of the invention also include non-transitory, tangible machine-readable media containing instructions or containing design data, such as Hardware Description Language (HDL), which defines structures, circuits, apparatuses, processors and/or system features described herein. Such embodiments may also be referred to as program products.

### Emulation (Including Binary Translation, Code Morphing, Etc.)

In some cases, an instruction converter may be used to convert an instruction from a source instruction set to a target instruction set. For example, the instruction converter may translate (e.g., using static binary translation, dynamic binary translation including dynamic compilation), morph, emulate, or otherwise convert an instruction to one or more other instructions to be processed by the core. The instruction converter may be implemented in software, hardware, firmware, or a combination thereof. The instruction converter may be on processor, off processor, or part on and part off processor.

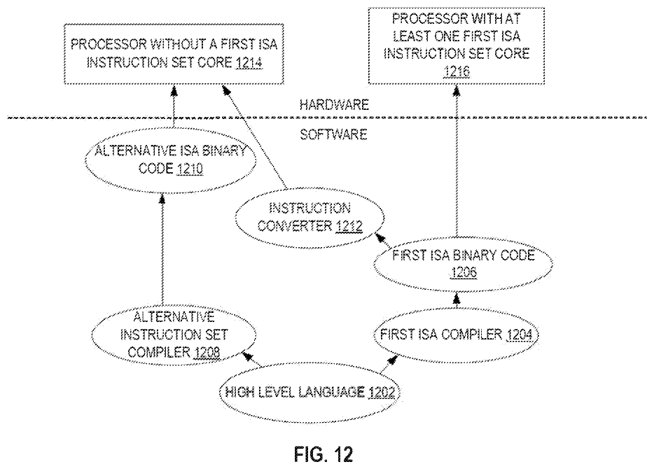

FIG. 12 illustrates a block diagram contrasting the use of a software instruction converter to convert binary instructions in a source instruction set to binary instructions in a target instruction set according to embodiments of the invention. In the illustrated embodiment, the instruction converter is a software instruction converter, although alternatively the instruction converter may be implemented in software, firmware, hardware, or various combinations thereof. FIG. 12 shows a program in a high level language 1202 may be compiled using a first ISA compiler 1204 to generate first ISA binary code 1206 that may be natively executed by a processor with at least one first instruction set core 1216. The processor with at least one first ISA instruction set core 1216 represents any processor that can perform substantially the same functions as an Intel® processor with at least one first ISA instruction set core by compatibly executing or otherwise processing (1) a substantial portion of the instruction set of the first ISA instruction set core or (2) object code versions of applications or other software targeted to run on an Intel processor with at least one first ISA instruction set core, in order to achieve substantially the same result as a processor with at least one first ISA instruction set core. The first ISA compiler 1204 represents a compiler that is operable to generate first ISA binary code 1206 (e.g., object code) that can, with or without additional linkage processing, be executed on the processor with at least one first ISA instruction set core 1216.

Similarly, FIG. 12 shows the program in the high level language 1202 may be compiled using an alternative instruction set compiler 1208 to generate alternative instruction set binary code 1210 that may be natively executed by a processor without a first ISA instruction set core 1214. The instruction converter 1212 is used to convert the first ISA binary code 1206 into code that may be natively executed by the processor without a first ISA instruction set core 1214. This converted code is not likely to be the same as the alternative instruction set binary code 1210 because an instruction converter capable of this is difficult to make; however, the converted code will accomplish the general operation and be made up of instructions from the alternative instruction set. Thus, the instruction converter 1212 represents software, firmware, hardware, or a combination thereof that, through emulation, simulation or any other process, allows a processor or other electronic device that does not have a first ISA instruction set processor or core to execute the first ISA binary code 1206.

### Embodiments of a Compression/Decompression Accelerator

One embodiment of the invention comprises a low area, high-throughput Deflate compression and decompression accelerator. Deflate is the most widely deployed lossless compression/decompression standard and is used in many software applications/libraries including, but not limited to, gzip, zlib, 7-zip, PNG, .ZIP etc. The Deflate operation is specified in its basic format in Request for Comments (RFC) 1951. While the embodiments of the invention described below focus on Deflate compression/decompression operations using Huffman coding, the underlying principles of the invention may be implemented on any form of prefix coding and may also be used in other forms of lossless compression algorithms.

The Deflate operation compresses raw data into a stream of literals and length+distance symbols that are subsequently Huffman encoded to achieve optimal compression. Each symbol is represented by a code varying in length from 1b-15b. Some of the length and distance codes require a variable number of additional bits (0-13b) from the payload that need concatenation with the Huffman decoded base during decompression. Hence, each compressed symbol can vary in length from 1b-28b. The variable length encoding along with the serial nature of Deflate algorithm makes it impossible to decode any subsequent symbol before processing the symbol that is the earliest in the compressed payload. This fundamental bottleneck of the algorithm limits decompression throughput on a single block to a theoretic 1 symbol/decode-cycle at best, irrespective of the number of cores and specialized hardware Huffman decoders available in a system.

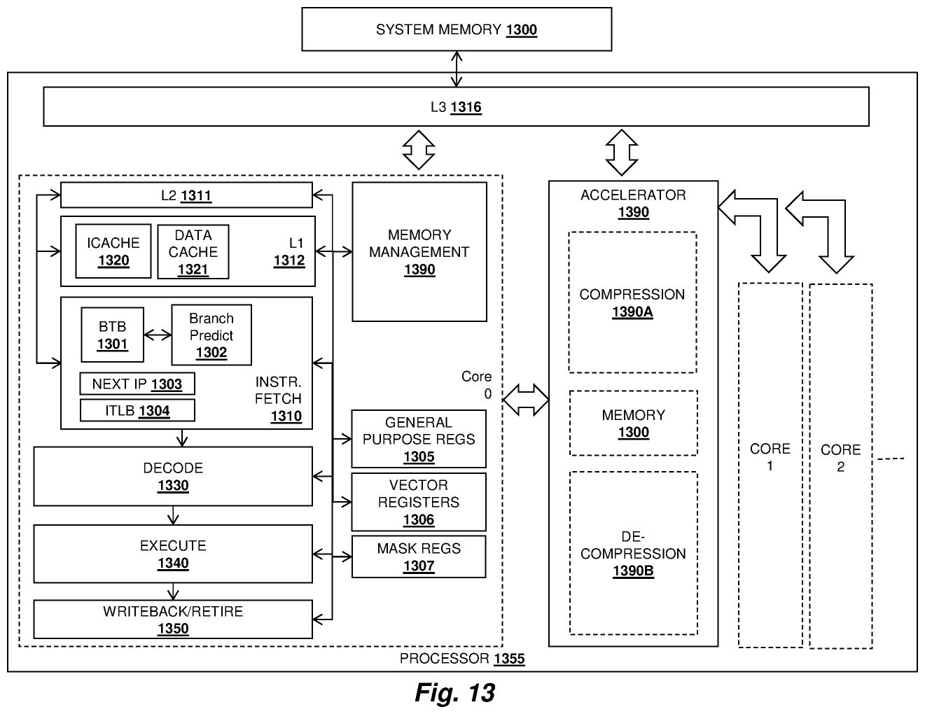

FIG. 13 illustrates an exemplary processor 1355 on which embodiments of the invention may be implemented. A compression/decompression accelerator 1390 comprising compression hardware logic 1390A and decompression hardware logic 1390B is included in the processor 1355 for performing the parallel, high throughput compression and decompression operations, respectively, as described herein. In the embodiment shown in FIG. 13, a single accelerator 1390 is shared by all of the cores 0, 1, 2, etc. In an alternate embodiment, each core 0, 1, 2, etc, includes its own instance of a compression/decompression accelerator 1390. In yet another embodiment, the compression/decompression accelerator 1390 may be implemented on a semiconductor chip separate from the semiconductor chip of the processor 1355, communicatively coupled to the processor over a communication link/bus. The underlying principles of the invention are not limited to any particular architectural arrangement for integrating the compression/decompression accelerator 1390 into a data processing system.

In one embodiment, each core 0-N of the processor 1355 includes memory management circuitry 1390 for performing memory operations such as load/store operations with system memory 1301. Although not illustrated, one embodiment of the compression/decompression accelerator 1390 also includes memory management circuitry to access main memory 1301 independently. For example, when a core needs to offload a compression or decompression job, it may write a descriptor into system memory 1301 indicating the type of operation, the source data to be compressed or decompressed, respectively, and the memory location where the results are to be stored.

Each core 0-N includes a set of general purpose registers (GPRs) 1305, a set of vector registers 1306, and a set of mask registers 1307. In one embodiment, multiple vector data elements are packed into each vector register 1306 which may have a 512 bit width for storing two 256 bit values, four 128 bit values, eight 64 bit values, sixteen 32 bit values, etc. However, the underlying principles of the invention are not limited to any particular size/type of vector data. In one embodiment, the mask registers 1307 include eight 64-bit operand mask registers used for performing bit masking operations on the values stored in the vector registers 1306 (e.g., implemented as mask registers k0-k7 described above). However, the underlying principles of the invention are not limited to any particular mask register size/type.

The details of a single processor core (“Core 0”) are illustrated in FIG. 13 for simplicity. It will be understood, however, that each core of the processor 1355 may have the same set of logic as Core 0. For example, each core may include a dedicated Level 1 (L1) cache 1312 and Level 2 (L2) cache 1311 for caching instructions and data according to a specified cache management policy. The L1 cache 1312 includes a separate instruction cache 1320 for storing instructions and a separate data cache 1321 for storing data. The instructions and data stored within the various processor caches are managed at the granularity of cache lines which may be a fixed size (e.g., 64, 128, 512 bytes in length). Each core of this exemplary embodiment has an instruction fetch unit 1310 for fetching instructions from main memory 1301 and/or a shared Level 3 (L3) cache 1316; a decode unit 1320 for decoding the instructions (e.g., decoding program instructions into micro-operations or “uops”); an execution unit 1340 for executing the instructions; and a writeback unit 1350 for retiring the instructions and writing back the results.

The instruction fetch unit 1310 includes various components including a next instruction pointer 1303 for storing the address of the next instruction to be fetched from memory 1301 (or one of the caches); an instruction translation look-aside buffer (ITLB) 1304 for storing a map of recently used virtual-to-physical instruction addresses to improve the speed of address translation; a branch prediction unit 1302 for speculatively predicting instruction branch addresses; and branch target buffers (BTBs) 1301 for storing branch addresses and target addresses. Once fetched, instructions are then streamed to the remaining stages of the instruction pipeline including the decode unit 1330, the execution unit 1340, and the writeback unit 1350.

### Embodiments of a Dictionary Compression Accelerator

One embodiment of the compression/decompression accelerator 1390 performs page-level decompression and compression in response to read and write operations, respectively, executed by the cores 0, 1, 2, etc. For example, to conserve space in the system memory 1301, the compression hardware logic 1390A compresses memory pages prior to storage in the system memory 1301 and the decompression hardware logic 1390B decompresses memory pages when read from the system memory 1301. The accelerator 1390 may have a local memory device 1300 for storing compression/decompression state and other relevant data.

The use of page-level compression to create a memory hierarchy or memory tiers, such as in the current Linux ZSWAP implementation, is becoming very important. Rather than paging memory pages out to disk, they are compressed and stored in memory, with the goal of increasing the effective memory capacity but with much better performance than swapping to a slower tier such as storage media. The ideal performance goal is to maximize the memory savings (via page compression) with nearly zero performance impact compared to running on a system with a much larger DRAM capacity (and no compression).

An obvious requirement for such a system is low latency compression and decompression. Such systems have typically used relatively lightweight compression algorithms such as Lempel-Ziv-Oberhumer (LZO) compression. This class of algorithm has the advantage of higher speed, but this comes at the cost of a reduced amount of compression.

With the advent of hardware compression accelerators such as those described above, it has become feasible to use more effective compression algorithms, such as Deflate, while still maintaining the latency at a reasonable level. The goal is still, however, to minimize the latency for compression and decompression while maximizing the compression ratio.

One way to enhance the ratio further is to implement a dictionary-processing feature in the compression hardware logic 1390B. In particular, one embodiment of the compression hardware logic 1390A uses a “preset dictionary” to pre-populate the history buffer to improve compression efficiency (e.g., encoding the input data in a more compact manner). The use of a preset dictionary as described herein is particularly useful at the start of the compression operation, and therefore tends to provide greater benefit when compressing smaller buffers.

The decompression hardware logic 1390B may subsequently be initialized with the appropriate context by virtually decompressing a compressed version of the dictionary without producing any output, or loading some state that reflects the context. The compressor and the decompressor must use exactly the same dictionary which may be fixed or may be chosen among a certain number of predefined dictionaries, according to the kind of input data being compressed.

One particular implementation of the compression hardware logic 1390A improves the compression ratio for Deflate compression by selecting the dictionary mode with minimal area cost and performance impact. A new mode of operation is provided for dictionary processing which controls how to load certain state derived from the dictionary as an initial state/context. Once that initial state is loaded, compression and decompression operations proceed as usual. The descriptions below focus primarily on the compression hardware logic 1390A, and mention the decompression hardware logic 1390B for the sake of completeness.

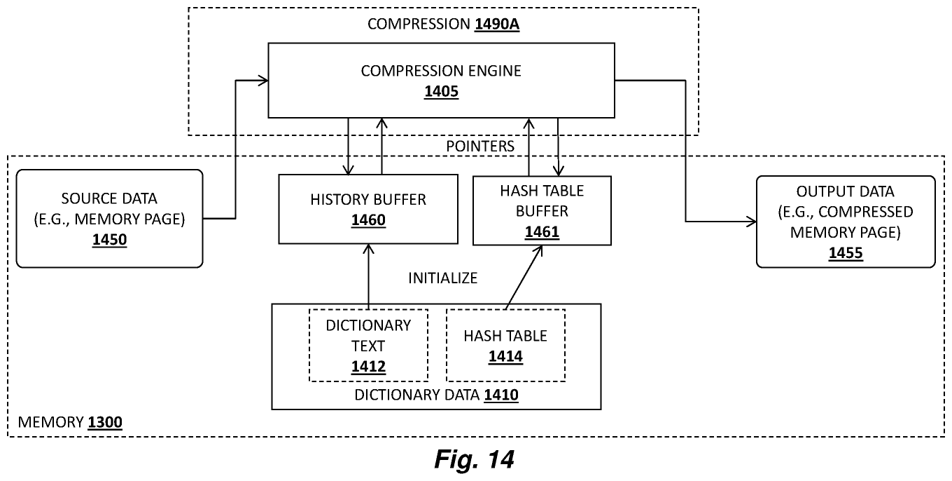

FIG. 14 illustrates the compression engine 1405 in one embodiment of the compression hardware logic 1390A which generates compressed output data 1455 (e.g., a compressed memory page) based on uncompressed source data 1450 (e.g., an uncompressed memory page) and dictionary data 1410. In this embodiment, a history buffer 1460 is constructed within the accelerator memory 1300 to store data to be used by the compression hardware logic 1390A to perform matches within the source data 1450. In one embodiment, this data comprises the most recent 4 KB (or other amount) of the uncompressed source data 1450 which has been processed by the compression hardware logic 1390A. A separate buffer 1461 is used to store the hash table used by compression engine 1405 to identify matches in the history buffer 1460 (as explained in details below). Other buffers may be used to store the various other data structures described herein, including the Huffman tables.

In one embodiment of the invention, in response to receiving a compression job to compress the source data 1450, the history buffer 1460 is initialized with the dictionary text 1412 of pre-configured dictionary data 1410. The compression engine 1405 of this embodiment then uses the dictionary text 1412 to compress the source data 1450 more efficiently during the early stages of the compression operation.

As illustrated, the dictionary data 1410 include both the dictionary text 1412 and a hash/indexing table 1414 which provides pointers or hints to the compression engine 1405 that indicate where the compression engine 1405 should look within the history buffer 1460 to match portions of the source data 1450. For example, for N bytes of source data 1450, the hash/index table 1414 may provide one or more pointers indicating where to find the the match within the history buffer 1460.

In one embodiment, the hash/index table 1414 comprises a pre-processed version of the dictionary text 1412. By way of example, and not limitation, a hash function executed by the compression engine 1405 may take in three bytes of source data and hash it to a 10-bit value which indexes one of a set of hash buckets (e.g., 1024) within the hash/index table 1414. In one embodiment, each hash bucket contains a specified number of pointers (e.g., 2, 4, etc) which the compression engine 1405 uses to locate a match within the history buffer 1460. In addition, a set of metadata bits may be provided with each pointer to provide a hint as to the next few bytes of the source data. In one embodiment, the compression engine 1405 uses the metadata bits to choose a subset of the pointers as being the most likely to result in a match (e.g., choosing 2 out of 4 pointers).

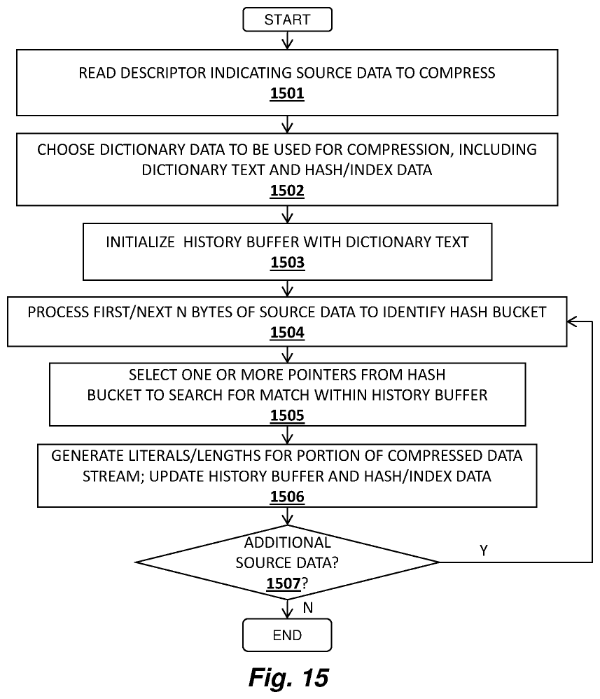

A method for performing compression by initializing the history buffer using preset dictionary data is illustrated in FIG. 15. The method may be implemented in the context of the processor and/or system architectures described above, but is not limited to any particular architecture.

At 1501, a descriptor is read from memory indicating source data to be compressed. For example, in one embodiment, one of the processor cores executing program code generates the descriptor to offload compression work to the compression accelerator. In one particular implementation, the descriptor includes the control and state data described herein.

At 1502, dictionary data is selected for the compression operation. As mentioned, the dictionary data may include dictionary text and hash/index data. At 1503, the history buffer is initialized with the dictionary text and, at 1504, the first/next N bytes (e.g., 3 bytes) of the source data is processed to generate a hash value, which is then used to identify a hash bucket within a hash/index table.

At 1505, one or more pointers are selected from the hash bucket (e.g., based on additional metadata bits in one embodiment). The pointers are then used to search for a match within the history buffer. As mentioned, four pointers may be included in the hash bucket and a subset of these may be selected based on metadata (e.g., 2 out of the 4).

At 1506, a portion of the compressed data stream is generated based on the results. For example, if a match is found, then a length value may be stored in the compressed data stream. If no match is found, then a new literal may be included in the compressed data stream.

If additional source data remains, determined at 1507, then the process repeats from 1504, where the next N bytes of the source data are used to identify a hash bucket. If no more source data remains at 1507, then the compression is complete.

In one embodiment of the compression engine 1405 chooses a mode of operation based on the size of the dictionary and the compression ratio vs compression performance trade-off. For example, the compression engine 1405 may use the dictionary data techniques described herein only for source data having a size less than a specified threshold (e.g., 16 kB or less, 8 kB or less, etc). In addition, as described below, the compression engine 1405 may select a particular dictionary size and/or hash/index table size based on the characteristics of the compression job to be performed. Alternatively, or in addition, the selection of a particular dictionary size and/or hash/index table size is made by the application using the compression engine.

In one embodiment, to initialize compression using a dictionary, a “load dictionary” flag is set within a control register or other data structure visible to the compression engine 1405. Once this flag is set, the selected dictionary data may be appended to the end or within a compression control/state data structure used to control the operation of the compression engine 1405.

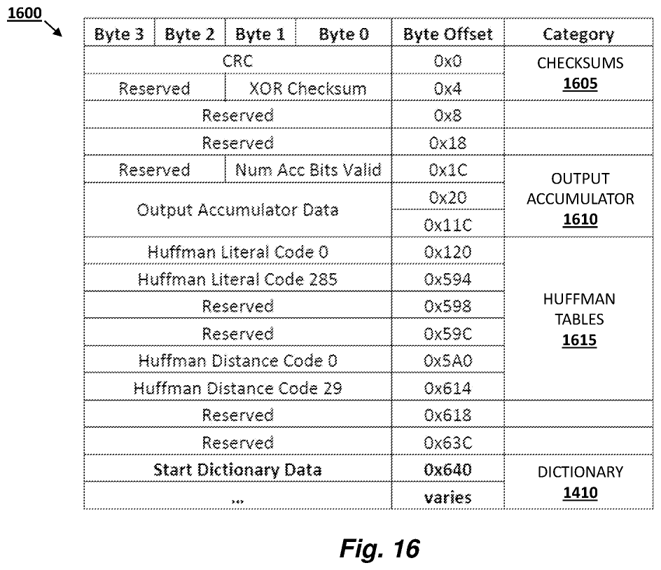

Referring to FIG. 16, one embodiment of the compression control/state data structure 1600 includes checksums 1605 (e.g., to protect the underlying data); an output accumulator 1610 to store accumulated output data and associated valid bits; the set of Huffman tables 1615 used for the encode/decode; and the dictionary data 1410 described above.

The dictionary data can be constructed in multiple different formats with multiple different sizes. While three sizes are provided in the example below, the underlying principles of the invention are not limited to this particular number. In general, the trade-off is that a larger size for the dictionary data will in general result in a better compression ratio, but it will also cause a longer latency for the compress operation. Some applications may find that the improvement in compression ratio is not worth the increase in compress latency and so opt for a smaller amount of dictionary data.

As described above, the dictionary data 1410 consists of two variable-length regions: the dictionary text 1412 that is actually being used, and the corresponding hash tables 1414 (generated a priori based on the dictionary text 1412). In one embodiment, different sizes of dictionary data 1410 are realized by adjusting the size of the dictionary text 1412 and the number of pointers for each entry of the hash tables 1414. In the example in Table 4 below, dictionary text of sizes 2K or 4K are selected in combination with 2 pointers/entry or 4 pointers/entry. The selection of how big the actual dictionary and hash table entries are is referred to as the dictionary “style” and is specified with descriptor flag bits.

TABLE 4

| Dictionary Style | Dictionary Text | Hash Table Size | Total Size |
|---|---|---|---|
| 2K Dictionary, | 2 kB | 4 kB | 6 kB |
| 2 Ptrs/Entry | | | |
| 4K Dictionary, | 4 kB | 4 kB | 8 kB |
| 2 Ptrs/Entry | | | |
| 4K Dictionary, | 4 kB | 8 kB | 12 kB |
| 4 Ptrs/Entry | | | |

In one embodiment, if the raw dictionary is larger than the size of the dictionary as specified by its style, then the final bytes of the raw dictionary are used as these are expected to have the most frequent patterns. If the raw dictionary is smaller, it should be prepended with zero bytes, so that the matches have the smallest distance, resulting in a smaller encoding.

With respect to decompression, one embodiment of the decompression hardware logic 1390B includes state storage and state processing logic to load the state from the compression control/state data structure 1600 at the start of a decompression job. As mentioned, the state may include input/output accumulator state 1610, decoder tables for the Huffman codes 1615, and history data such as the dictionary data 1410.

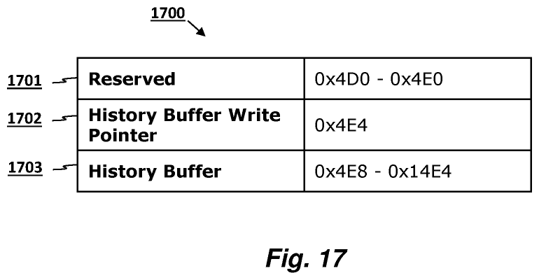

As illustrated in FIG. 17, in one implementation, the decompression internal state 1700 is defined to be at the end of the compression control/state data structure 1600. The final fields in this embodiment include a Reserved field 1701, the History Buffer Write Pointer field 1702, and the History Buffer field 1703. This allows an efficient mechanism to optimize performance for deflate decompress with a dictionary in cases where the dictionary is smaller than the history buffer. The compression control/state data structure 1600 size is set to be just the right size to read the write pointer field and just the required size of the history (e.g. 2 KB) and not the maximum size (e.g., 4 KB).

One embodiment of the decompression hardware logic 1390B compresses data in multiple chunks. When the dictionary decompression techniques are implemented as described herein, the decompression operation is essentially the same as decompressing the (compressed) dictionary, saving the state, and then loading that state and decompressing the real bit stream. The primary difference is that for dictionary usage, software generates the saved state rather than the hardware.

One embodiment optimizes loading a compression control/state data structure 1600 of a smaller size when a smaller dictionary is used; an optimization which is often inapplicable to the decompression of a large file through multiple chunks since each chunk is typically larger than 4 KB.

In one embodiment of the decompression hardware logic 1390B, the state to be loaded is the raw dictionary bytes. Here, performance can be optimized simply by setting a smaller value for the size of the compression control/state data structure 1600.

In one embodiment, to create the state for the compressor, a software library is executed to generate the hash tables 1414 needed for the three modes highlighted above. In this embodiment, the software is configured with parameters based on the microarchitecture of the accelerator 1390 and generates the three modes based on these parameters.

In another embodiment, a mode of operation is defined in the compression engine 1390A to dump state. For example, the dictionary may be provided as input and the compression operation set up (with suppressed output) to write out state. Some variations here are related to whether the software performs post-processing. In a simpler version, the accelerator 1390 dumps out the entire hash table state (e.g., including all four pointers per entry), which the software will post-process if it needs a subset. In another implementation, the accelerator 1390 is also provided with input parameters indicating which mode of dictionary state is needed, and it generates an exact compression control/state data structure 1600 for compressing data using this dictionary.

Embodiments of the invention which perform DRAM memory tiering based on compression may be controlled by the operating system (OS), virtual machine monitor (VMM), or other privileged control software transparent to applications. Accesses to memory pages are tracked to distinguish between pages which are accessed frequently (“hot” pages) and those which are not (“cold” pages) over a particular time interval. In one implementation, cold pages are compressed and stored into a compressed region of memory while hot pages are not compressed, or are compressed less rigorously.

In other embodiments, memory pages may be categorized with greater precision than hot/cold. For example, memory pages may be assigned an activity value within a specified range (e.g., between 1 and 4) with more frequently accessed pages categorized towards the top of the range and less frequently accessed pages towards the bottom.

In addition, application program code may provide hints to achieve improved compression results. In one embodiment, pre-training is performed on the application code during runtime to generate a dictionary to be used for its pages.

While the embodiments of the invention were described above with reference to specific forms of compression, the underlying principles of the invention are not limited to these specific details. Embodiments of the invention may be implementation using other forms of dictionary compression added to different algorithms (e.g., within databases such as Cassandra and RocksDB).

In the foregoing specification, the embodiments of invention have been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

### EXAMPLES

The following are example implementations of different embodiments of the invention.

Example 1. An apparatus comprising: a plurality of cores; a compression/decompression accelerator coupled to or integral to one or more of the plurality of cores, the compression/decompression accelerator to perform decompression and compression operations in response to read and write operations, respectively, wherein responsive to notification of a compression job to compress a memory page or a portion thereof, a history buffer associated with the compression/decompression accelerator to is to be initialized with pre-configured dictionary data, the compression/decompression accelerator to match portions of the pre-configured dictionary data with portions of the memory page to generate compressed output data.

Example 2. The apparatus of example 1 wherein the compression/decompression accelerator is to further be provided with hash tables associated with the pre-configured dictionary data, the compression/decompression accelerator to read pointers from the hash tables based on sequences of bytes from the memory page.

Example 3. The apparatus of example 2 wherein the compression/decompression accelerator is to use the pointers to attempt to match the portions of the pre-configured dictionary data with the portions of the memory page to generate the compressed output data.

Example 4. The apparatus of example 3 wherein the compression/decompression accelerator further comprises: hash logic to execute a hash function using each of the sequences of bytes from the memory page to generate an N-bit value and to use the N-bit value to index one of a set of hash buckets of the hash tables.

Example 5. The apparatus of example 4 wherein the sequences of bytes from the memory page comprises three consecutive bytes and wherein the N-bit value comprises a 10-bit value.

Example 6. The apparatus of example 2 wherein the hash tables comprise a pre-processed version of the dictionary data.

Example 7. The apparatus of example 2 wherein the hash tables and pre-configured dictionary data are selected based on characteristics of the compression job and/or the memory page.

Example 8. The apparatus of example 7 wherein the hash tables and pre-configured dictionary data are selected from a pre-configured group of dictionary styles, including a first dictionary style comprising dictionary data of a first size and hash tables of a first size, a second dictionary style comprising dictionary data of a second size and hash tables of the first size, and a third dictionary style comprising dictionary data of the second size and hash tables of a second size.

Example 9. The apparatus of example 8 wherein the first dictionary style comprises 2 KB dictionary data and 4 KB hash tables, the second dictionary style comprises 4 KB dictionary data and 4 KB hash tables, and the third dictionary style comprises 4 KB dictionary data and 8 KB hash tables.

Example 10. The apparatus of example 2 wherein the compression/decompression accelerator is to append a compression state data structure including the hash tables and associated pre-configured dictionary data to the compressed output data prior to storing or transmitting the compressed output data.

Example 11. The apparatus of example 10 wherein compression/decompression accelerator is to include Huffman tables, output accumulator data, and checksums in the compression state data structure.

Example 12. A method comprising: initializing a history buffer with pre-configured dictionary data in response to notification of a compression job to perform compression of a memory page or a portion thereof; reading pointers from hash tables associated with the pre-configured dictionary data based on sequences of bytes from the memory page; and attempting to match portions of the pre-configured dictionary data identified based on the pointers with portions of the memory page to generate compressed output data.

Example 13. The method of example 12 further comprising: executing a hash function using each of the sequences of bytes from the memory page to generate an N-bit value; and using the N-bit value to index one of a set of hash buckets of the hash tables.

Example 14. The method of example 13 wherein the sequences of bytes from the memory page comprises three consecutive bytes and wherein the N-bit value comprises a 10-bit value.

Example 15. The method of example 12 wherein the hash tables comprise a pre-processed version of the dictionary data.

Example 16. The method of example 12 wherein the hash tables and pre-configured dictionary data are selected based on characteristics of the compression job and/or the memory page.

Example 17. The method of example 16 wherein the hash tables and pre-configured dictionary data are selected from a pre-configured group of dictionary styles, including a first dictionary style comprising dictionary data of a first size and hash tables of a first size, a second dictionary style comprising dictionary data of a second size and hash tables of the first size, and a third dictionary style comprising dictionary data of the second size and hash tables of a second size.

Example 18. The method of example 17 wherein the first dictionary style comprises 2 KB dictionary data and 4 KB hash tables, the second dictionary style comprises 4 KB dictionary data and 4 KB hash tables, and the third dictionary style comprises 4 KB dictionary data and 8 KB hash tables.

Example 19. The method of example 12 further comprising:

appending a compression state data structure including the hash tables and associated pre-configured dictionary data to the compressed output data prior to storing or transmitting the compressed output data.

Example 20. The method of example 19 wherein the compression state data structure is to further include Huffman tables, output accumulator data, and checksums in the compression state data structure.

Example 25. A machine-readable medium having program code stored thereon which, when executed by a machine, causes the machine to perform the operations of: initializing a history buffer with pre-configured dictionary data in response to notification of a compression job to perform compression of a memory page or a portion thereof; reading pointers from hash tables associated with the pre-configured dictionary data based on sequences of bytes from the memory page; and attempting to match portions of the pre-configured dictionary data identified based on the pointers with portions of the memory page to generate compressed output data.

Example 26. The machine-readable medium of example 25 further comprising program code to cause the machine to perform the operations of: executing a hash function using each of the sequences of bytes from the memory page to generate an N-bit value; and using the N-bit value to index one of a set of hash buckets of the hash tables.

Example 27. The machine-readable medium of example 26 wherein the sequences of bytes from the memory page comprises three consecutive bytes and wherein the N-bit value comprises a 10-bit value.

Example 28. The machine-readable medium of example 25 wherein the hash tables comprise a pre-processed version of the dictionary data.

Example 29. The machine-readable medium of claim 25 wherein the hash tables and pre-configured dictionary data are selected based on characteristics of the compression job and/or the memory page.

Example 30. The machine-readable medium of example 29 wherein the hash tables and pre-configured dictionary data are selected from a pre-configured group of dictionary styles, including a first dictionary style comprising dictionary data of a first size and hash tables of a first size, a second dictionary style comprising dictionary data of a second size and hash tables of the first size, and a third dictionary style comprising dictionary data of the second size and hash tables of a second size.

Example 31. The machine-readable medium of example 30 wherein the first dictionary style comprises 2 KB dictionary data and 4 KB hash tables, the second dictionary style comprises 4 KB dictionary data and 4 KB hash tables, and the third dictionary style comprises 4 KB dictionary data and 8 KB hash tables.

Example 32. The machine-readable medium of example 25 further comprising program code to cause the machine to perform the operations of: appending a compression state data structure including the hash tables and associated pre-configured dictionary data to the compressed output data prior to storing or transmitting the compressed output data.

Example 33. The machine-readable medium of example 32 wherein the compression state data structure is to further include Huffman tables, output accumulator data, and checksums in the compression state data structure.

Embodiments of the invention may include various steps, which have been described above. The steps may be embodied in machine-executable instructions which may be used to cause a general-purpose or special-purpose processor to perform the steps. Alternatively, these steps may be performed by specific hardware components that contain hardwired logic for performing the steps, or by any combination of programmed computer components and custom hardware components.

As described herein, instructions may refer to specific configurations of hardware such as application specific integrated circuits (ASICs) configured to perform certain operations or having a predetermined functionality or software instructions stored in memory embodied in a non-transitory computer readable medium. Thus, the techniques shown in the Figures can be implemented using code and data stored and executed on one or more electronic devices (e.g., an end station, a network element, etc.). Such electronic devices store and communicate (internally and/or with other electronic devices over a network) code and data using computer machine-readable media, such as non-transitory computer machine-readable storage media (e.g., magnetic disks; optical disks; random access memory; read only memory; flash memory devices; phase-change memory) and transitory computer machine-readable communication media (e.g., electrical, optical, acoustical or other form of propagated signals—such as carrier waves, infrared signals, digital signals, etc.). In addition, such electronic devices typically include a set of one or more processors coupled to one or more other components, such as one or more storage devices (non-transitory machine-readable storage media), user input/output devices (e.g., a keyboard, a touchscreen, and/or a display), and network connections. The coupling of the set of processors and other components is typically through one or more busses and bridges (also termed as bus controllers). The storage device and signals carrying the network traffic respectively represent one or more machine-readable storage media and machine-readable communication media. Thus, the storage device of a given electronic device typically stores code and/or data for execution on the set of one or more processors of that electronic device. Of course, one or more parts of an embodiment of the invention may be implemented using different combinations of software, firmware, and/or hardware. Throughout this detailed description, for the purposes of explanation, numerous specific details were set forth in order to provide a thorough understanding of the present invention. It will be apparent, however, to one skilled in the art that the invention may be practiced without some of these specific details. In certain instances, well known structures and functions were not described in elaborate detail in order to avoid obscuring the subject matter of the present invention. Accordingly, the scope and spirit of the invention should be judged in terms of the claims which follow.

What is claimed is:

1. An apparatus comprising:
a plurality of cores;
a compression/decompression accelerator coupled to or integral to one or more of the plurality of cores, the compression/decompression accelerator to perform decompression and compression operations in response to read and write operations, respectively,
wherein responsive to notification of a compression job to compress a memory page or a portion thereof, a history buffer associated with the compression/decompression accelerator to is to be initialized with pre-configured dictionary data, the compression/decompression accelerator to match portions of the pre-configured dictionary data with portions of the memory page to generate compressed output data.

2. The apparatus of claim 1 wherein the compression/decompression accelerator is to further be provided with hash tables associated with the pre-configured dictionary data, the compression/decompression accelerator to read pointers from the hash tables based on sequences of bytes from the memory page.

3. The apparatus of claim 2 wherein the compression/decompression accelerator is to use the pointers to attempt to match the portions of the pre-configured dictionary data with the portions of the memory page to generate the compressed output data.

4. The apparatus of claim 3 wherein the compression/decompression accelerator further comprises:
hash logic to execute a hash function using each of the sequences of bytes from the memory page to generate an N-bit value and to use the N-bit value to index one of a set of hash buckets of the hash tables.

5. The apparatus of claim 4 wherein the sequences of bytes from the memory page comprises three consecutive bytes and wherein the N-bit value comprises a 10-bit value.

6. The apparatus of claim 2 wherein the hash tables comprise a pre-processed version of the dictionary data.

7. The apparatus of claim 2 wherein the hash tables and pre-configured dictionary data are selected based on characteristics of the compression job and/or the memory page.

8. The apparatus of claim 7 wherein the hash tables and pre-configured dictionary data are selected from a pre-configured group of dictionary styles, including a first dictionary style comprising dictionary data of a first size and hash tables of a first size, a second dictionary style comprising dictionary data of a second size and hash tables of the first size, and a third dictionary style comprising dictionary data of the second size and hash tables of a second size.

9. The apparatus of claim 8 wherein the first dictionary style comprises 2 KB dictionary data and 4 KB hash tables, the second dictionary style comprises 4 KB dictionary data and 4 KB hash tables, and the third dictionary style comprises 4 KB dictionary data and 8 KB hash tables.

10. The apparatus of claim 2 wherein the compression/decompression accelerator is to append a compression state data structure including the hash tables and associated pre-configured dictionary data to the compressed output data prior to storing or transmitting the compressed output data.

11. The apparatus of claim 10 wherein compression/decompression accelerator is to include Huffman tables, output accumulator data, and checksums in the compression state data structure.

12. A method comprising:
initializing a history buffer with pre-configured dictionary data in response to notification of a compression job to perform compression of a memory page or a portion thereof;
reading pointers from hash tables associated with the pre-configured dictionary data based on sequences of bytes from the memory page; and
attempting to match portions of the pre-configured dictionary data identified based on the pointers with portions of the memory page to generate compressed output data.

13. The method of claim 12 further comprising:
executing a hash function using each of the sequences of bytes from the memory page to generate an N-bit value; and
using the N-bit value to index one of a set of hash buckets of the hash tables.

14. The method of claim 13 wherein the sequences of bytes from the memory page comprises three consecutive bytes and wherein the N-bit value comprises a 10-bit value.

15. The method of claim 12 wherein the hash tables comprise a pre-processed version of the dictionary data.

16. The method of claim 12 wherein the hash tables and pre-configured dictionary data are selected based on characteristics of the compression job and/or the memory page.

17. The method of claim 16 wherein the hash tables and pre-configured dictionary data are selected from a pre-configured group of dictionary styles, including a first dictionary style comprising dictionary data of a first size and hash tables of a first size, a second dictionary style comprising dictionary data of a second size and hash tables of the first size, and a third dictionary style comprising dictionary data of the second size and hash tables of a second size.

18. The method of claim 17 wherein the first dictionary style comprises 2 KB dictionary data and 4 KB hash tables, the second dictionary style comprises 4 KB dictionary data and 4 KB hash tables, and the third dictionary style comprises 4 KB dictionary data and 8 KB hash tables.

19. The method of claim 12 further comprising:
appending a compression state data structure including the hash tables and associated pre-configured dictionary data to the compressed output data prior to storing or transmitting the compressed output data.

20. The method of claim 19 wherein the compression state data structure is to further include Huffman tables, output accumulator data, and checksums in the compression state data structure.

25. A machine-readable medium having program code stored thereon which, when executed by a machine, causes the machine to perform the operations of:
initializing a history buffer with pre-configured dictionary data in response to notification of a compression job to perform compression of a memory page or a portion thereof;
reading pointers from hash tables associated with the pre-configured dictionary data based on sequences of bytes from the memory page; and
attempting to match portions of the pre-configured dictionary data identified based on the pointers with portions of the memory page to generate compressed output data.

26. The machine-readable medium of claim 25 further comprising program code to cause the machine to perform the operations of:
executing a hash function using each of the sequences of bytes from the memory page to generate an N-bit value; and
using the N-bit value to index one of a set of hash buckets of the hash tables.

27. The machine-readable medium of claim 26 wherein the sequences of bytes from the memory page comprises three consecutive bytes and wherein the N-bit value comprises a 10-bit value.

28. The machine-readable medium of claim 25 wherein the hash tables comprise a pre-processed version of the dictionary data.

29. The machine-readable medium of claim 25 wherein the hash tables and pre-configured dictionary data are selected based on characteristics of the compression job and/or the memory page.

30. The machine-readable medium of claim 29 wherein the hash tables and pre-configured dictionary data are selected from a pre-configured group of dictionary styles, including a first dictionary style comprising dictionary data of a first size and hash tables of a first size, a second dictionary style comprising dictionary data of a second size and hash tables of the first size, and a third dictionary style comprising dictionary data of the second size and hash tables of a second size.

31. The machine-readable medium of claim 30 wherein the first dictionary style comprises 2 KB dictionary data and 4 KB hash tables, the second dictionary style comprises 4 KB dictionary data and 4 KB hash tables, and the third dictionary style comprises 4 KB dictionary data and 8 KB hash tables.

32. The machine-readable medium of claim 25 further comprising program code to cause the machine to perform the operations of:
appending a compression state data structure including the hash tables and associated pre-configured dictionary data to the compressed output data prior to storing or transmitting the compressed output data.

33. The machine-readable medium of claim 32 wherein the compression state data structure is to further include Huffman tables, output accumulator data, and checksums in the compression state data structure.
